(19) United States
(12) Patent Application Publication
(10) Pub. No.: US 2021/0132259 A1
(43) Pub. Date: May 6, 2021

(54) DISPLAY DEVICE

(71) Applicant: Wuhan China Star Optoelectronics Semiconductor Display Technology Co., Ltd., Wuhan, Hubei (CN)

(72) Inventor: Fang WANG, Wuhan, Hubei (CN)

(21) Appl. No.: 16/768,934

(22) PCT Filed: Jan. 14, 2020
(86) PCT No.: PCT/CN2020/071907

§ 371 Date: Jun. 2, 2020

(30) Foreign Application Priority Data
Sep. 12, 2019 (CN) 201910863061.3

(51) Int. Cl. G02B 1/14; G06F 1/16; G02B 1/04

(52) U.S. Cl. CPC G02B 1/14; G02B 5/3025; G02B 1/04; G06F 1/1609

(57) ABSTRACT

The present invention provides a display device. By setting opposite surfaces of the substrate and the hard coat layer of the glass cover plate as uneven structures, not only flatness of the glass cover plate can be ensured, but also stress can be dispersed under point impact. Meanwhile, upper and lower sides of the protection layer are provided with uneven structures at the same time, such that the stress can also be diffused, and the buffer layer is formed by flattening the upper and lower sides of the protection layer to make the entire buffer layer smoother. The display device of the present invention can increase resistance to point impacts and reduce local injuries.

### BACKGROUND OF INVENTION

### Field of Invention

The present invention relates to a field of display, and in particular to a display device.

### Description of Prior Art

Organic light-emitting diode (OLED) display devices often use organic films with good bending performance as glass cover plates in order to meet the bending characteristics. In order to improve the hardness, hard coat material is usually spin-coated on organic substrates. to achieve the purpose of hardening a surface layer, but its hardness is still significantly lower than the glass cover.

Therefore, after being subjected to a point impact, the stress usually cannot be dispersed quickly, and a panel is deformed more severely due to local stress concentration, causing damage to a screen. Meanwhile, in a current module stack structure, contact surfaces between various layers are mostly horizontal contact surfaces, and although its preparation process is simple, it is not conducive to stress dispersion after being subjected to the point impact.

Therefore, there is a need to propose a new display device to improve the effect of dispersing stress on the display device after being impacted, so as to better protect the display panel.

### SUMMARY OF INVENTION

An object of the present invention is to provide a display device. By setting opposite surfaces of the substrate and the hard coat layer of the glass cover plate as uneven structures, not only flatness of the glass cover plate can be ensured, but also stress can be dispersed under point impact.

The present invention provides a display device, including: a middle frame; a buffer layer disposed on the middle frame; a support layer disposed on the buffer layer; a display panel disposed on a side of the support layer away from the buffer layer; a polarizer disposed on a side of the display panel away from the support layer; and a glass cover plate disposed on a side of the polarizer away from the display panel, wherein the glass cover plate includes a substrate and a hard coat layer disposed on the substrate, the substrate is disposed on the polarizer, a side of the substrate away from the polarizer is provided with a plurality of first protrusions, a side of the hard coat layer close to the substrate is provided with a plurality of first grooves, the first protrusions and the first grooves have same shapes and sizes, and the first protrusions are correspondingly snapped into the first grooves.

Further, the first protrusions and the first grooves have cross-sectional shapes including an arc shape, a triangle shape, a square shape, or combinations thereof.

Further, the buffer layer includes a first planarization layer disposed on the middle frame and provided with a plurality of second protrusions; and a protection layer disposed on a side of the first planarization layer away from the middle frame, and provided with a plurality of second grooves on a side of the protection layer close to the first planarization layer, wherein the second protrusions and the second grooves have same shapes and sizes, and the second protrusions are correspondingly snapped into the second grooves.

Further, a side of the protection layer away from the first planarization layer is provided with a plurality of third protrusions, and the buffer layer further includes a second planarization layer disposed on a side of the protection layer away from the first planarization layer, and provided with a plurality of third grooves on a side of the second planarization layer close to the protection layer, wherein, the third protrusions and the third grooves have same the shapes and sizes, and the third protrusions are correspondingly snapped into the third grooves.

Further, the second protrusions and the second grooves have cross-sectional shapes including an arc shape, a triangle shape, a square shape, or combinations thereof.

Further, the third protrusions and the third grooves have cross-sectional shapes including an arc shape, a triangle shape, a square shape, or combinations thereof.

Further, the substrate is made of a material including colorless polyimide or polyterephthalate plastic.

Further, the first planarization layer is made of a material including an optically clear adhesive.

Further, the second planarization layer is made of a material including an optically clear adhesive.

The present invention provides a display device. By setting opposite surfaces of the substrate and the hard coat layer of the glass cover plate as uneven structures, not only flatness of the glass cover plate can be ensured, but also stress can be dispersed under point impact. Meanwhile, upper and lower sides of the protection layer are provided with uneven structures at the same time, such that the stress can also be diffused, and the buffer layer is formed by flattening the upper and lower sides of the protection layer to make the entire buffer layer smoother. The display device of the present invention can increase resistance to point impacts and reduce local injuries.

### BRIEF DESCRIPTION OF DRAWINGS

In order to more clearly illustrate the embodiments or the technical solutions of the existing art, the drawings illustrating the embodiments or the existing art will be briefly described below. Obviously, the drawings in the following description merely illustrate some embodiments of the present invention. Other drawings may also be obtained by those skilled in the art according to these figures without paying creative work.

FIG. 1 is a schematic structural diagram of a display device according to the present invention.

FIG. 2 is a schematic diagram of a stress dispersion structure of a display device according to the present invention.

Display device 100; middle frame 101; buffer layer 102;

Support layer 103; display panel 104; polarizer 105;

Glass cover plate 106; first planarization layer 1021; protection layer 1022;

Second planarization layer 1023; substrate 1061; hard coat layer 1062;

First protrusion 1061a; second protrusion 1021a; third protrusion 1022b;

First groove 1062a; second groove 1022a; third groove 1023a;

Stress 10, 20, 30.

### DETAILED DESCRIPTION OF PREFERRED EMBODIMENTS

The following is a description of each embodiment with reference to additional drawings to illustrate specific embodiments in which the present invention can be implemented. The directional terms mentioned in the present invention, such as up, down, front, back, left, right, inside, outside, side, etc., are only directions referring to the drawings. The nomenclature of the elements mentioned in the present invention, such as first, second, etc., are only used to distinguish different component parts, for better expression. In the drawings, structurally similar elements are denoted by the same reference numerals.

Embodiments of the present invention will be described in detail herein with reference to the drawings. The present invention may take many different forms, and the present invention should not be construed as merely the specific embodiments set forth herein. The embodiments of the present invention are provided to explain the practical application of the present invention, so that those skilled in the art can understand various embodiments of the present invention and various modifications suitable for a specific intended application.

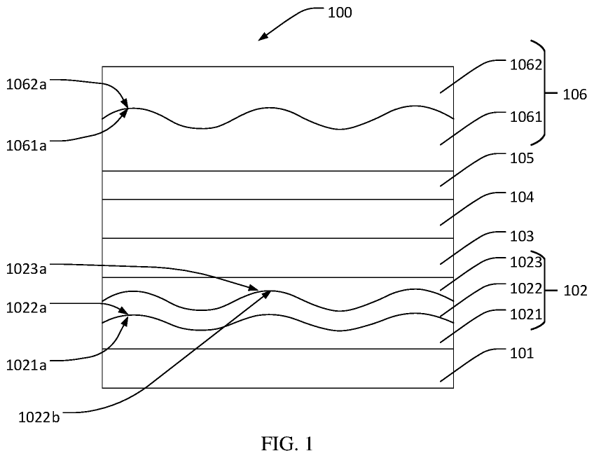

As shown in FIG. 1, the present invention provides a display device 100 including a middle frame 101, a buffer layer 102, a support layer 103, a display panel 104, a polarizer 105, and a glass cover plate 106 arranged sequentially.

The glass cover plate 106 includes a substrate 1061 and a hard coat layer 1062. The hard coat layer 1062 is provided on the substrate 1061, and the substrate 1061 is provided on the polarizer 105. The substrate 1061 is made of a material original translation 4 including colorless polyimide or polyterephthalate plastic. The substrate 1061 has a plurality of first protrusions 1061a on a side away from the polarizer 105.

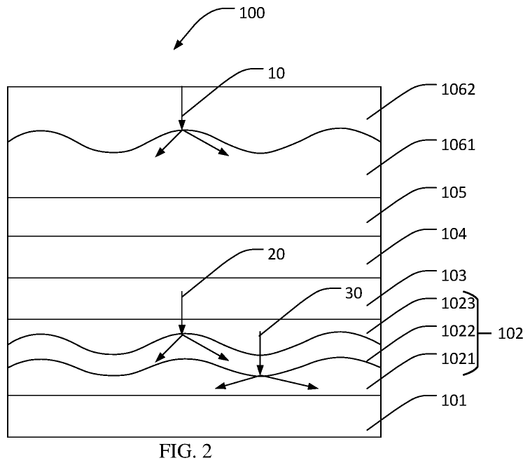

Cross-sectional shapes of the first protrusions 1061a include an arc shape, a triangle shape, a square shape, or combinations thereof. The first protrusions 1061a of the present invention are preferably arc-shaped, so as to form a continuous concave-convex wave structure, which can diffuse the stress generated by point impact (referring to FIG. 2, the stress 10 vertically enters the hard coat layer 1062, and is dispersed due to the uneven structure on the upper side of the substrate).

The hard coat is made of an organic material. The hard coat layer 1062 has a plurality of first grooves 1062a on a side close to the substrate 1061. The first protrusions 1061a and the first grooves 1062a have the same shapes and sizes. The first protrusions 1061a are correspondingly snapped into the first grooves 1062a.

Cross-sectional shapes of the first grooves 1062a include an arc shape, a triangle shape, a square shape, or combinations thereof. The cross-sectional shapes of the first protrusions 1061a correspond to the shapes of the first grooves 1062a, so that the upper and lower surfaces of the glass cover plate 106 can be made flat.

The buffer layer 102 is disposed on the middle frame 101. The buffer layer 102 includes a first planarization layer 1021, a protection layer 1022, and a second planarization layer 1023.

The first planarization layer 1021 is disposed on the middle frame 101 and provided with a plurality of second protrusions 1021a. The first planarization layer 1021 is made of a material including an optical clear adhesive.

The protection layer 1022 is disposed on a side of the first planarization layer 1021 away from the middle frame 101, and the protection layer 1022 is provided with a plurality of second grooves 1022a on a side close to the first planarization layer 1021.

The second protrusions 1021a and the second grooves 1022a have the same shapes and sizes. The second protrusions 1021a are correspondingly snapped into the second grooves 1022a.

The continuous second grooves 1022a form an uneven structure on a side of the protection layer 1022 to disperse vertical stress (referring to FIG. 2, the stress 20 enters the protection layer 1022 vertically, and stress is dispersed due to the uneven structure on the upper side), thereby protecting the display device 100. The first planarization layer 1021 is used to make a side of the protection layer 1022 more smooth.

Cross-sectional shape of the second protrusions 1021a and the second grooves 1022a include an arc shape, a triangle shape, a square shape, or combinations thereof. The shapes of the second grooves 1022a correspond to the shapes of the second protrusions 1021a, and the first planarization layer 1021 can make a side of the protection layer 1022 smooth.

The protection layer 1022 is provided with a plurality of third protrusions 1022b on a side away from the first planarization layer 1021, and another side of the protection layer 1022 also forms a continuous uneven structure for dispersing vertically downward stress (referring to FIG. 2, the stress 30 enters the protection layer 1022 vertically, and the stress is dispersed due to the uneven structure on the lower side), thereby protecting the display device 100.

The second planarization layer 1023 is disposed on a side of the protection layer 1022 away from the first planarization layer 1021. The material of the second planarization layer 1023 includes an optical clear adhesive.

A plurality of third grooves 1023a are formed on a side of the second planarization layer 1023 closed to the protection layer 1022.

Each of the third protrusions 1022b and each of the third grooves 1023a have the same shapes and sizes. The third protrusions 1022b are correspondingly snapped into the third grooves 1023a. The second planarization layer 1023 is used to make another side of the protection layer 1022 more smooth.

Cross-sectional shape of the third protrusions 1022b and the third grooves 1023a include an arc shape, a triangle shape, and a square shape, or combinations thereof. The shapes of the third grooves 1023a correspond to the shapes of the third protrusions 1022b, and the second planarization layer 1023 can make another side of the protection layer 1022 smooth.

The support layer 103 is disposed on the buffer layer 102; the display panel 104 is disposed on a side of the support layer 103 away from the buffer layer 102; and the polarizer 105 is disposed on a side of the display panel 104 away from the support layer 103.

The glass cover plate 106 is disposed on a side of the polarizer 105 away from the display panel 104.

The present invention provides a display device 100. By setting opposite surfaces of the substrate 1061 and the hard coat layer of the glass cover plate 106 as uneven structures, not only flatness of the glass cover plate 106 can be ensured, but also stress can be dispersed under point impact. Meanwhile, upper and lower sides of the protection layer 1022 are provided with uneven structures at the same time, such that the stress can also be diffused, and the buffer layer 102 is formed by flattening the upper and lower sides of the protection layer 1022 to make the entire buffer layer 102 smoother. The display device of the present invention can increase resistance to point impacts and reduce local injuries.

The technical scope of the present invention is not limited to the content in the description, and those skilled in the art can make various variations and modifications to the embodiment without departing from the technical idea of the present invention, and these variations and modifications should be within the scope of the present invention.

What is claimed is:

1. A display device, comprising
a middle frame;
a buffer layer disposed on the middle frame;
a support layer disposed on the buffer layer;
a display panel disposed on a side of the support layer away from the buffer layer;
a polarizer disposed on a side of the display panel away from the support layer; and
a glass cover plate disposed on a side of the polarizer away from the display panel,
wherein the glass cover plate comprises a substrate and a hard coat layer disposed on the substrate, the substrate is disposed on the polarizer, a side of the substrate away from the polarizer is provided with a plurality of first protrusions, a side of the hard coat layer close to the substrate is provided with a plurality of first grooves, the first protrusions and the first grooves have same shapes and sizes, and the first protrusions are correspondingly snapped into the first grooves.

2. The display device according to claim 1, wherein
the first protrusions and the first grooves have cross-sectional shapes comprising an arc shape, a triangle shape, or a square shape.

3. The display device according to claim 1, wherein the buffer layer comprises
a first planarization layer disposed on the middle frame and provided with a plurality of second protrusions; and
a protection layer disposed on a side of the first planarization layer away from the middle frame, and provided with a plurality of second grooves on a side of the protection layer close to the first planarization layer,
wherein the second protrusions and the second grooves have same shapes and sizes, and the second protrusions are correspondingly snapped into the second grooves.

4. The display device according to claim 3, wherein
a side of the protection layer away from the first planarization layer is provided with a plurality of third protrusions, and
the buffer layer further comprises
a second planarization layer disposed on a side of the protection layer away from the first planarization layer, and provided with a plurality of third grooves on a side of the second planarization layer close to the protection layer,
wherein, the third protrusions and the third grooves have same the shapes and sizes, and the third protrusions are correspondingly snapped into the third grooves.

5. The display device according to claim 3, wherein
the second protrusions and the second grooves have cross-sectional shapes comprising an arc shape, a triangle shape, or a square shape.

6. The display device according to claim 4, wherein
the third protrusions and the third grooves have cross-sectional shapes comprising an arc shape, a triangle shape, or a square shape.

7. The display device according to claim 1, wherein
the substrate is made of a material comprising colorless polyimide or polyterephthalate plastic.

8. The display panel according to claim 1, wherein
the hard coat layer is made of an organic material.

9. The display panel according to claim 3, wherein
the first planarization layer is made of a material comprising an optically clear adhesive.

10. The display panel according to claim 4, wherein
the second planarization layer is made of a material comprising an optically clear adhesive.
